(19) United States
(12) Patent Application Publication
(10) Pub. No.: US 2023/0133652 A1
(43) Pub. Date: May 4, 2023

(54) SYSTEMS AND METHODS FOR UNCERTAINTY PREDICTION USING MACHINE LEARNING

(71) Applicant: GE Grid GmbH, Frankfurt Am Main (DE)

(72) Inventors: Jinbo Cao, Rexford, NY (US); Richard Louis Hart, Broadalbin, NY (US); David John Smith, Clifton Park, NY (US)

(21) Appl. No.: 17/514,396

(22) Filed: Oct. 29, 2021

(51) Int. Cl. G01R 31/392; G01R 31/382; G06N 20/00; G06K 9/62

(52) U.S. Cl. CPC G01R 31/392; G01R 31/382; G06N 20/00; G06K 9/6257

(57) ABSTRACT

A system for uncertainty prediction is provided. The system includes at least one target system including at least one target device and configured to generate data corresponding to a plurality of parameters of the target device. The system further includes a computing device including a processor configured to receive, during a training phase, first data obtained from the at least one target system, perform a Monte Carlo simulation to generate a first plurality of uncertainty intervals based on the first data, and generate a machine learning model by training using the first plurality of uncertainty intervals and the first data. The processor is further configured to receive, during a prediction phase, second data from the at least one target system and generate, using the machine learning model, a second plurality of uncertainty intervals based on the second data.

### BACKGROUND

The field of the invention relates generally to uncertainty prediction, and more particularly, to systems for uncertainty prediction in battery energy storage systems.

An operating lifetime for a device or system, such as a battery, may be predicted based on stress factors experienced by the device or system during its operation using a cumulative damage model. Because, in a cumulative damage model, an error value corresponding to the next future timestep depends on historical values, analytical methodology to determine or predict the error is extremely difficult. Existing methods for prediction interval estimation in a cumulative damage model, such as a Monte Carlo error simulation, are relatively slow and computationally expensive, and therefore are not suitable for real-time computation of uncertainty with respect to the lifetime of a system. An improved system for predicting uncertainty is therefore desirable.

### BRIEF DESCRIPTION

In one aspect, a system for uncertainty prediction is provided. The system includes at least one target system including at least one target device and configured to generate data corresponding to a plurality of parameters of the at least one target device. The system further includes a computing device including a processor. The processor is configured to receive, during a training phase, first data obtained from the at least one target system. The processor is further configured to perform a Monte Carlo simulation to generate a first plurality of uncertainty intervals based on the first data. The processor is further configured to generate a machine learning model by training using the first plurality of uncertainty intervals and the first data. The processor is further configured to receive, during a prediction phase, second data from the at least one target system. The processor is further configured to generate, using the machine learning model, a second plurality of uncertainty intervals based on the second data.

In another aspect, a method for uncertainty prediction performed by an uncertainty prediction computing device including a processor. The method includes, receiving, by the uncertainty prediction computing device during a training phase, first data obtained from at least one target system including at least one target device is provided. The method further includes performing, by the uncertainty prediction computing device, a Monte Carlo simulation to generate a first plurality of uncertainty intervals based on the first data. The method further includes generating, by the uncertainty prediction computing device, a machine learning model by training using the first plurality of uncertainty intervals and the first data. The method further includes receiving, by the uncertainty prediction computing device during a prediction phase, second data from the at least one target system. The method further includes generating, by the uncertainty prediction computing device using the machine learning model, a second plurality of uncertainty intervals based on the second data.

In another aspect, an uncertainty prediction computing device is provided. The uncertainty prediction computing device includes a processor in communication. The processor is configured to receive, during a training phase, first data obtained from at least one target system including at least one target device. The processor is further configured to perform a Monte Carlo simulation to generate a first plurality of uncertainty intervals based on the first data. The processor is further configured to generate a machine learning model by training using the first plurality of uncertainty intervals and the first data. The processor is further configured to receive, during a prediction phase, second data from the at least one target system. The processor is further configured to generate, using the machine learning model, a second plurality of uncertainty intervals based on the second data.

### DRAWINGS

These and other features, aspects, and advantages of the present disclosure will become better understood when the following detailed description is read with reference to the accompanying drawings in which like characters represent like parts throughout the drawings, wherein:

FIG. 1 is a block diagram of an example uncertainty prediction system.

FIG. 2 is a graph illustrating an example uncertainty bound curve for a battery.

FIG. 3 is a flowchart of an example method for uncertainty prediction.

FIG. 4 is a flowchart of another example method for uncertainty prediction.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The embodiments described herein include a system for uncertainty prediction. The system includes at least one target system that includes at least one target device and that is configured to generate data corresponding to a plurality of parameters of the at least one target device. The target system may be, for example, a battery system, a lighting system, or other system having components that may be analyzed using a cumulative damage model.

The system further includes a computing device that includes a processor in communication with the at least one target system. The processor is configured to operate in a training phase and a prediction phase. In the training phase, the processor is configured to receive first data obtained from the at least one target system and perform a Monte Carlo simulation to generate a first plurality of uncertainty intervals based on the first data. Using the first plurality of uncertainty intervals and the first data as training data, the processor is configured to generate a machine learning model based on the first plurality of uncertainty intervals and the first data using for example, a partial least squares (PLS) regression.

During the prediction phase, the processor is configured to receive second data from the at least one target system and generate a second plurality of uncertainty intervals using the machine learning model. In some embodiments, the processor may receive additional data and use the additional data to further train the machine learning model.

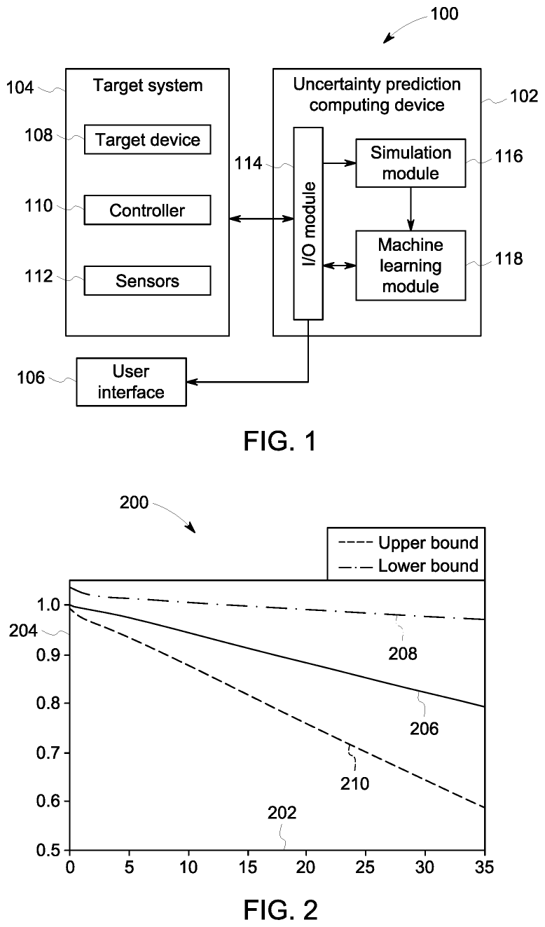

FIG. 1 is a block diagram illustrating an example uncertainty prediction system 100. Uncertainty prediction system 100 includes an uncertainty prediction computing device 102, at least one target system 104, and a user interface 106.

Target system 104 includes at least one target device 108, and in some embodiments, further includes a controller 110 configured to monitor and/or control operation of target device 108 and/or one or more sensors 112 configured to measure and/or detect parameters of target device 108. As described in further detail below, uncertainty prediction computing device 102 determines an uncertainty interval for one or more parameters, such as a lifetime, of target device 108 based on data obtained from target system 104. Target device 108 may be any device having a lifetime that can be modeled for cumulative damage such as, for example, a battery. While FIG. 1 depicts target device 108 as an active device that may be controlled by controller 110, in some embodiments, target device 108 may be a passive device and/or object, and a controller such as controller 110 may not be present. Data may be generated by target device 108, controller 110, and/or sensors 112. In example embodiments in which target system 104 is a battery system and target device 108 is a battery, such data may include, for example, time, temperature, voltage, state of charge, depth of discharge, charge rate, charge frequency, and/or other parameters.

Uncertainty prediction computing device 102 includes an input/output (I/O) module 114, a simulation module 116, and a machine learning module 118, which may be implemented using hardware, software executed on a processor of uncertainty prediction computing device 102, or a combination thereof. I/O module 114 is configured to receive data from target system 104 and to facilitate transmission of such data to other components of uncertainty prediction computing device 102. I/O module 114 may further facilitate displaying data or receiving user input via user interface 106.

Uncertainty prediction computing device 102 is configured to operate in a training phase. In the training phase, uncertainty prediction computing device 102 is configured to receive first data obtained from target system 104. The data may be received directly from target system 104 in real time, or may be received from a database that includes historical data obtained from target system 104. In some embodiments, target system 104 may be operated according to a training routine, where controller 110 may cycle target device 108 though a plurality of different operating conditions, and corresponding data may be connected. In some embodiments, uncertainty prediction computing device 102 is configured to cause target system 104 to operate according to the training routine using instructions that define the training routine. For example, in embodiments in which target system 104 is a battery system, target system 104 may be tested under cycles such as charge, high voltage hold, discharge, and low voltage hold.

Uncertainty prediction computing device 102 includes a simulation module 116 configured to perform a Monte Carlo simulation to generate a first plurality of uncertainty intervals based on the first data. To perform the Monte Carlo simulation, simulation module 116 computes standard deviation estimates based on the first data obtained from target system 104. Simulation module 116 simulates using a relatively large number of input values based on the standard deviation estimates by using the standard deviation estimates to randomly and/or pseudo-randomly select the input values. The simulation produces an output distribution, of which simulation module 116 computes a standard deviation, which in turn is used by simulation module 116 to determine a first plurality of uncertainty intervals. The first plurality of uncertainty intervals may be used by uncertainty prediction computing device 102 as training data for a machine learning model, which may be used to determine updated uncertainty intervals based on new data. Accordingly, once the machine learning model has been generated, uncertainty prediction computing device 102 does not need to repeat the computationally expensive Monte Carlo simulation.

Uncertainty prediction computing device 102 further includes a machine learning module 118 configured generate a machine learning model. Machine learning module 118 uses the first plurality of uncertainty intervals generated using the Monte Carlo simulation to train the machine learning model. In some embodiments, machine learning module 118 generates the machine learning model using a PLS regression to identify a relationship between the input first data and the corresponding first uncertainty interval computed using the Monte Carlo simulation. As described in further detail below, this relationship may be used to compute an uncertainty interval based on future input data.

Uncertainty prediction computing device 102 is further configured to operate in a prediction mode. In the prediction mode, uncertainty prediction computing device 102 is configured to receive second data from target system 104. Using the second data, machine learning module 118 generates a second plurality of uncertainty intervals using the machine learning model. Using machine learning module 118, uncertainty prediction computing device 102 may also use data received during the prediction phase to further train or retrain the machine learning model, after which further computations of uncertainty intervals may be made.

FIG. 2 is a graph 200 illustrating an example uncertainty bound curve for a battery that may be generated using uncertainty prediction system 100. Graph 200 includes a horizontal axis 202 representing elapsed time expressed in years. Graph 200 further includes a vertical axis 204 representing charge capacity expressed as a dimensionless ratio. Graph 200 further includes an average prediction curve 206 representing a predicted average lifetime of the battery, an upper uncertainty curve 208, and a lower uncertainty curve 210. Upper uncertainty curve 208 and lower uncertainty curve 210 may be computed using machine learning techniques, as described with respect to FIG. 1.

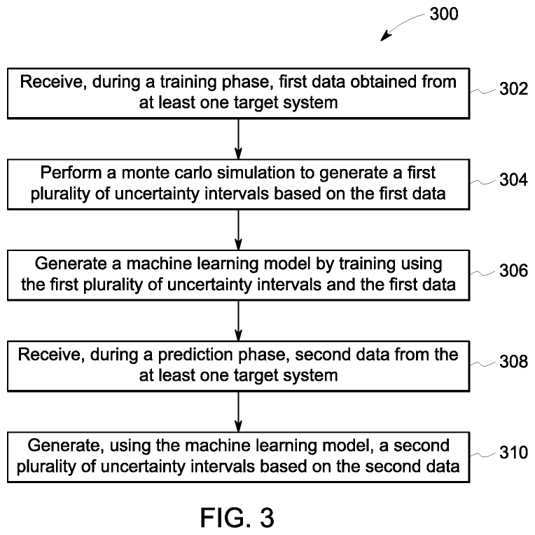

FIG. 3 is a flowchart illustrating an example method 300 for uncertainty prediction. In some embodiments, method 300 is performed by an uncertainty prediction system such as uncertainty prediction system 100 (shown in FIG. 1) using a processor of uncertainty prediction computing device 102.

Method 300 includes receiving 302, during a training phase, first data obtained from at least one target system (such as target system 104). The first data is generated by the target system and corresponds to parameters of a target device (such as target device 108). In certain embodiments, at least one target system includes an energy storage system. For example, in some such embodiments, the target system is a battery system and the target device is a battery.

In some embodiments, the first data includes stress factors of the target device, such as factors that may influence a lifetime of the target device. For example, in embodiments wherein the target device is a battery, the first data may include one or more of time, temperature, voltage, state of charge, depth of discharge, charge rate, and charge frequency.

Method 300 further includes performing 304 a Monte Carlo simulation to generate a first plurality of uncertainty intervals based on the first data. In certain embodiments, the uncertainty intervals correspond to a cumulative damage model for the target device. For example, in embodiments wherein the target device is a battery, the uncertainty intervals may correspond to a lifetime of the battery.

Method 300 further includes generating 306 a machine learning model by training using the first plurality of uncertainty intervals and the first data. In certain embodiments, generating the machine learning model includes performing a partial least square regression using the first plurality of uncertainty intervals and first data as training data.

Method 300 further includes receiving 308, during a prediction phase, second data from the at least one target system. The second data corresponds to the same parameters defined by the first data such as, for example, that factors that may influence a lifetime of the target device.

Method 300 further includes generating 310 a second plurality of uncertainty intervals based on the second data using the machine learning model. For example, the second data may be used as input data for the machine learning model, and the machine learning model may output the second plurality of uncertainty intervals. Like the first plurality of uncertainty intervals, the second plurality of uncertainty intervals may correspond to parameters such as a lifetime of the target device. In certain embodiments, the first plurality of uncertainty intervals and the second plurality of uncertainty intervals correspond to the cumulative damage model.

In some embodiments, method 300 further includes receiving third data from the at least one target system and retraining the machine learning model based on the third data. The third data may correspond to, for example, the same parameters as the first and second data, and be used as additional training data for the machine learning model. In such embodiments, new uncertainty intervals may be computed after the machine learning model is retrained.

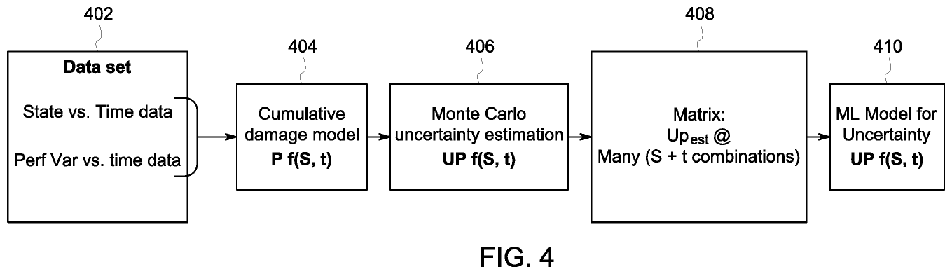

FIG. 4 is a flowchart illustrating an example method 400 that may be implemented using uncertainty prediction system 100 to predict uncertainty based on cumulative damage model. A data set 402 includes state versus time (t) data and performance variable versus time (t) data for target device such as target device 108. Data set 402 is modeled based on cumulative damage model 404 to represent the performance variable (P) as a function of time (t) and stress or state factors (S), which are variables that cause a change in a degradation rate of the performance variable. A Monte Carlo uncertainty estimation simulation 406 determines a corresponding uncertainty for specific combinations of time and stress factors, which form a matrix 408. The supporting data for Monte Carlo uncertainty estimation simulation 406 may come from lab or field testing. In addition, this model can be repeated or updated over time. A machine learning model 410 is trained using the data of matrix 408 to relate the original variations in time (t) and state (S) factors to the output of Monte Carlo uncertainty estimation simulation 406. Machine learning model 410 can be used to quickly compute uncertainty for give time and stress factor inputs.

An example technical effect of the methods, systems, and apparatus described herein includes at least one of: (a) reducing time and energy needed to compute uncertainty intervals by generating a machine learning model by training using data obtained from a target system and uncertainty intervals computed using a Monte Carlo simulation; and (b) reducing time and energy needed to compute uncertainty intervals by retraining a machine learning model using data obtained from a target system during operation after building the machine learning model.

Example embodiments of an uncertainty prediction computer system are provided herein. The systems and methods of operating and manufacturing such systems and devices are not limited to the specific embodiments described herein, but rather, components of systems and/or steps of the methods may be utilized independently and separately from other components and/or steps described herein. For example, the methods may also be used in combination with other electronic systems, and are not limited to practice with only the electronic systems, and methods as described herein. Rather, the example embodiments can be implemented and utilized in connection with many other electronic systems.

Some embodiments involve the use of one or more electronic or computing devices. Such devices typically include a processor, processing device, or controller, such as a general purpose central processing unit (CPU), a graphics processing unit (GPU), a microcontroller, a reduced instruction set computer (RISC) processor, an application specific integrated circuit (ASIC), a programmable logic circuit (PLC), a field programmable gate array (FPGA), a digital signal processing (DSP) device, and/or any other circuit or processing device capable of executing the functions described herein. The methods described herein may be encoded as executable instructions embodied in a computer readable medium, including, without limitation, a storage device and/or a memory device. Such instructions, when executed by a processing device, cause the processing device to perform at least a portion of the methods described herein. The above embodiments are examples only, and thus are not intended to limit in any way the definition and/or meaning of the term processor and processing device.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A system for uncertainty prediction, said system comprising:
at least one target system comprising at least one target device and configured to generate data corresponding to a plurality of parameters of said at least one target device; and
a computing device comprising a processor, said processor configured to:
receive, during a training phase, first data obtained from said at least one target system;
perform a Monte Carlo simulation to generate a first plurality of uncertainty intervals based on the first data;
generate a machine learning model by training using the first plurality of uncertainty intervals and the first data;
receive, during a prediction phase, second data from said at least one target system; and
generate, using the machine learning model, a second plurality of uncertainty intervals based on the second data.

2. The system of claim 1, wherein said processor is further configured to:
receive third data obtained from said at least one target system; and
retrain the machine learning model based on the third data.

3. The system of claim 1, wherein to generate the machine learning model, said processor is configured to perform a partial least square regression.

4. The system of claim 1, wherein the first plurality of uncertainty intervals and the second plurality of uncertainty intervals correspond to a cumulative damage model.

5. The system of claim 1, wherein the first data and the second data include stress factors of said at least one target device.

6. The system of claim 1, wherein said at least one target system comprises an energy storage system.

7. The system of claim 6, wherein said at least one target device comprises a battery.

8. The system of claim 7, wherein the first plurality of uncertainty intervals and the second plurality of uncertainty intervals correspond to a lifetime of said battery.

9. The system of claim 7, wherein the first data and the second data correspond to one or more of time, temperature, voltage, state of charge, depth of discharge, charge rate, and charge frequency.

10. A method for uncertainty prediction performed by an uncertainty prediction computing device including a processor, said method comprising:
receiving, by the uncertainty prediction computing device during a training phase, first data obtained from at least one target system including at least one target device;
performing, by the uncertainty prediction computing device, a Monte Carlo simulation to generate a first plurality of uncertainty intervals based on the first data;
generating, by the uncertainty prediction computing device, a machine learning model by training using the first plurality of uncertainty intervals and the first data;
receiving, by the uncertainty prediction computing device during a prediction phase, second data from the at least one target system; and
generating, by the uncertainty prediction computing device using the machine learning model, a second plurality of uncertainty intervals based on the second data.

11. The method of claim 10, further comprising:
receiving, by the uncertainty prediction computing device, third data obtained from the at least one target system; and
retraining, by the uncertainty prediction computing device, the machine learning model based on the third data.

12. The method of claim 10, wherein generating the machine learning model comprises performing, by the uncertainty prediction computing device, a partial least square regression.

13. The method of claim 10, wherein the first plurality of uncertainty intervals and the second plurality of uncertainty intervals correspond to a cumulative damage model.

14. The method of claim 10, wherein the first data and the second data include stress factors of the at least one target device.

15. The method of claim 10, wherein the at least one target system includes an energy storage system.

16. The method of claim 15, wherein the at least one target device includes a battery.

17. The method of claim 16, wherein the first plurality of uncertainty intervals and the second plurality of uncertainty intervals correspond to a lifetime of the battery.

18. The method of claim 16, wherein the first data and the second data correspond to one or more of time, temperature, voltage, state of charge, depth of discharge, charge rate, and charge frequency.

19. An uncertainty prediction computing device comprising a processor, said processor configured to:
receive, during a training phase, first data obtained from at least one target system including at least one target device;
perform a Monte Carlo simulation to generate a first plurality of uncertainty intervals based on the first data;
generate a machine learning model by training using the first plurality of uncertainty intervals and the first data;
receive, during a prediction phase, second data from the at least one target system; and
generate, using the machine learning model, a second plurality of uncertainty intervals based on the second data.

20. The uncertainty prediction computing device of claim 19, wherein said processor is further configured to:
receive third data from obtained from the at least one target system; and
retrain the machine learning model based on the third data.
